(19) United States
(12) Patent Application Publication
(10) Pub. No.: US 2006/0099803 A1
(43) Pub. Date: May 11, 2006

(54) Thin film capacitor

(76) Inventor: Yongki Min, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/974,139

(22) Filed: Oct. 26, 2004

(51) Int. Cl. H01L 21/4763

(52) U.S. Cl. 438/643

(57) ABSTRACT

A method including forming a barrier material on a surface of an electrode of a capacitor structure; forming a ceramic material on the electrode material; and annealing the ceramic material, wherein the barrier material comprises a material having a property that inhibits the oxidation of a material for the electrode during annealing of the ceramic material. An apparatus including a first electrode; a second electrode; a ceramic material disposed between the first electrode and the second electrode; and a barrier material between the ceramic material and at least one of the first electrode and the second electrode. A method including forming a ceramic material on a surface of an electrode of a capacitor structure; and annealing the ceramic material through a rapid thermal anneal process.

### BACKGROUND

1. Field

Integrated circuit structure and packaging.

2. Background

It is desirable to provide decoupling capacitance in a close proximity to an integrated circuit chip or die. The need for such capacitance increases as the switching speed and current requirements of chips or dies becomes higher. One way to provide decoupling capacitance through a chip or die is through an interposer substrate between a chip and a package that includes one or more thin film capacitors. Utilizing an interposer substrate between a chip and a package substrate allows capacitance to be approximate to a chip without utilizing real estate on a chip or an associated substrate package. Such configuration tends to improve the capacitance on power supply lines for the chip. A second way to provide decoupling capacitance is by integrating one or more thin film capacitors into a package substrate.

Representatively, thin film capacitors may be formed of electrodes of a platinum material in patterned sheets and a dielectric material (e.g., metal oxide materials) between the electrodes. Platinum as a material for the electrode will not oxidize at high processing temperatures in air, such as temperatures that might be used to sinter ceramic dielectric. Platinum, however, has a relatively high raw material cost and a high electrical resistivity compared to the cost and resistivity of nickel or copper. Platinum must also be sputter-deposited (physical vapor deposition (PVD)) with a maximum deposition thickness on the order of 0.2 micrometers. Copper and nickel can be electroplated to a thickness of several microns making these metal materials more favorable for circuit design considerations. However, these metal materials are easily oxidized at high processing temperatures, such as will be seen in sintering of a ceramic material of the capacitor dielectric. A typical ceramic annealing (sintering) temperature is on the order of 700° C. to 900° C. for several hours. If a reducing atmosphere is used during the sintering of a ceramic to avoid oxidation of an electrode material, the ceramic can be reduced to a conducting (leaky) state. At certain working electric fields (e.g., two volts, 0.1 micron), free charge carriers in the ceramic material generated under a reducing atmosphere can migrate to an electrode causing space charge formation (charge separation), and accompanying Schottky emission of electrons from the cathode (negative electrodes) into the dielectric to maintain a charge neutrality; this process leads to the irreversible increase of leakage current and break-down of the capacitor.

The high sintering temperatures (700° C.-900° C.) of a ceramic dielectric material is also comparable to the melting point of copper (approximately 1085° C.). Thus, under these sintering conditions, copper atoms can be highly diffusive and grain growth of copper can take place rapidly (e.g., recrystallization). The result may be protrusion of larger copper grains on a surface that can contribute to a short between top and bottom electrodes of a capacitor, particularly with thin (e.g., on the order of one micron) dielectric layers.

### BRIEF DESCRIPTION OF THE DRAWINGS

Features, aspects, and advantages of embodiments will become more thoroughly apparent from the following detailed description, appended claims, and accompanying drawings in which:

FIG. 1 shows a cross-sectional view of a package substrate located between a die and a base substrate.

FIG. 2 shows a magnified view of a portion of a package substrate of FIG. 1.

FIG. 3 shows a flow chart of a method of forming a capacitor.

FIG. 4 shows a cross-sectional view of a die mounted on a base substrate having a capacitor integrated therewith.

### DETAILED DESCRIPTION

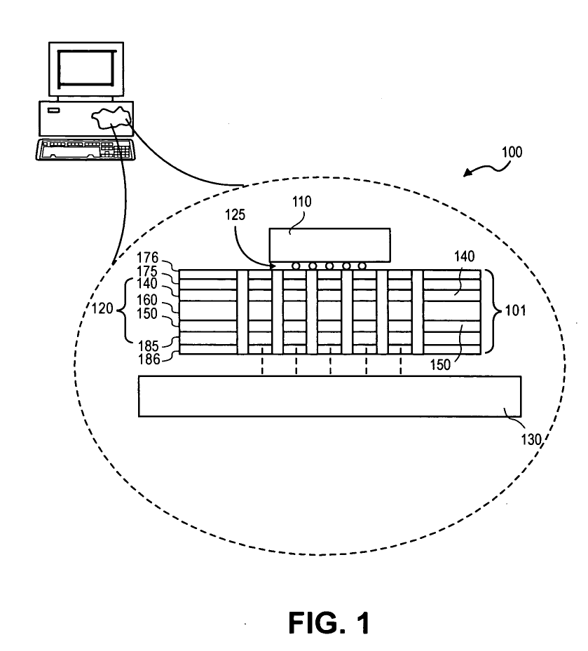

FIG. 1 shows a cross-sectional side view of an integrated circuit package that can be physically and electrically connected to a printed wiring board or printed circuit board (PCB) to form an electronic assembly. The electronic assembly can be part of an electronic system such as a computer (e.g., desktop, laptop, hand-held, server, etc.), wireless communication device (e.g., cellular phone, cordless phone, pager, etc.), computer-related peripheral (e.g., printers, scanner, monitors, etc.), entertainment device (e.g., television, radio, stereo, tape and compact disc player, videocassette recorder, MP3

(Motion Picture Experts Group, Audio Layer 3) player, etc.), and the like. FIG. 1 illustrates the package as part of a desktop computer.

FIG. 1 shows electronic assembly 100 including die 110 physically and electrically connected to package substrate 101. Die 110 is an integrated circuit die, such as a processor die. Electrical contact points (e.g., contact pads on a surface of die 110) are connected to package substrate 101 through conductive bump layer 125. Package substrate 101 may be used to connect electronic assembly 100 to printed circuit board 130, such as a motherboard or other circuit board.

In one embodiment, package substrate 101 includes one or more embedded capacitor structures. Referring to FIG. 1, package substrate 101 includes capacitor structure 140 connected to one side of core substrate 160. Capacitor structure 150 is connected to an opposite side of core substrate 160. In one embodiment, core substrate 160 is an organic core such as an epoxy including a fiberglass reinforced material, also called pre-preg. This configuration may be referred to as an integrated thin film capacitor (iTFC) system, where the capacitor(s) is(are) integrated into the package substrate rather than, for example, an interposer between the die and the package substrate. Overlying capacitor structure 140 is adhesion layer 175 of, for example, a polymer such as aminobenzodifuranon (ABF). Underlying capacitor structure 150 is dielectric layer 185 (e.g., ABF). Overlying adhesion layer 175 is build-up layer 176. Underlying dielectric layer 185 is build-up layer 186. Each build-up layer may include conductive vias and traces (e.g., copper traces) for lateral translation of contact points between die 110 and package substrate 101, and package substrate 101 and printed circuit board 130, respectively. The region made up of the combination of layers 185, 150, 160, 140 and 175, respectively, is referred to herein as functional core 120.

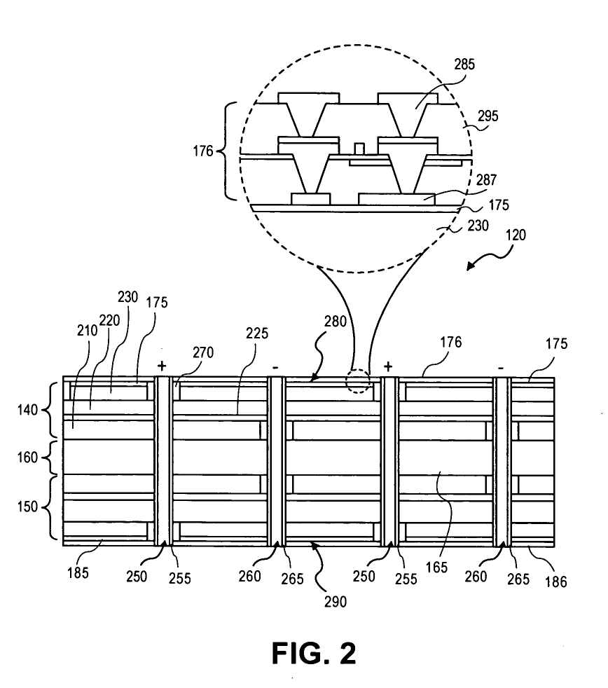

FIG. 2 shows a magnified view of a portion of functional core 120. Functional core 120 includes core substrate 160 having a thickness, in one embodiment, on the order of 200 microns (μm) to 700 μm. In another embodiment, core substrate 160 has a thickness on the order of 200 μm to 300 μm. In one embodiment, core substrate 160 is a glass-fiber (silica) reinforced epoxy.

Capacitor structure 140 is connected to one side of core substrate 160 (a top side as viewed). Capacitor structure 140 includes first conductor 210 proximal to core substrate 160 and second conductor 230. Disposed between first conductor 210 and second conductor 230 is high k dielectric material 220. Capacitor structure 150 is connected to an opposite side of core substrate 160 (a bottom side as viewed) and has a similar configuration of a dielectric material disposed between two conductors. Overlying capacitor structure 140 and capacitor structure 150 of functional core 120 (on sides opposite sides facing core substrate 160) is adhesion layer 175 and adhesion layer 185, respectively, of, for example, an organic material and having a representative thickness on the order of 10 microns (μm) to 50 μm. Build-up layer 176 and build-up layer 186 are formed on these adhesion layers. The build-up layers may include conductive vias, traces and contact points to connect package substrate to a chip or die and to a printed circuit board, respectively. An inset in FIG. 2 shows build-up layer 176 including two levels of conductive vias 285 and traces 287 disposed in dielectric material 295 of ABF.

In one embodiment, first conductor 210 and second conductor 230 of capacitor structure 140 are electrically conductive material. Suitable materials include, but are not limited to, a nickel or a copper material. A representative thickness of first conductor 210 and second conductor 220 is on the order of 10 μm to 50 μm.

In one embodiment, dielectric material 220 is a ceramic material having a relatively high dielectric constant (high-k). Representatively, a high-k material is a ceramic material having a dielectric constant on the order of 100 to 1,000. Suitable materials for dielectric material 220 include, but are not limited to, barium titanate (BaTiO₃), barium strontium titanate (Ba, Sr) TiO₃), and strontium titanate (SrTiO₃). A representative thickness of dielectric material 220 of a high-k ceramic material of a thickness on the order of 1 μm and, in another embodiment, less than 1 μm. Capacitor structure 150, in one embodiment, is similar to capacitor structure 140.

FIG. 2 also shows a barrier layer 225 on a surface of first conductive layer 210 between first conductive layer 210 and dielectric material 220. A similar barrier layer may be disposed on at least one conductive layer between the conductive layer and the dielectric material utilized in the capacitor. In one embodiment, barrier layer 225 is a material that will inhibit the diffusion of atoms of a material for first conductive layer 210. In another embodiment, barrier layer 225 is a material that will inhibit the oxidation of a material of first conductive layer 210. In another embodiment, barrier layer 225 is a material that will inhibit both diffusion of atoms from a material for first conductive layer 210 and inhibit the oxidation of a material of first conductive layer 210.

Suitable materials for barrier layer 225 include oxidation resistant metals, including but not limited to nickel and platinum. An alternative material for barrier layer 225 is a conductive ceramic, including but not limited to, titanium nitride. A representative thickness for barrier layer 225 of an oxidation resistant metal or a conductive ceramic is on the order of less than one micron. A further material for barrier layer 225 may be a metal material that tends to form a stable oxide relative to an oxide formed by first conductive layer 210. Representatively, metals such as aluminum, titanium, yandium, titanium-aluminum, etc. tend to be more dense than copper and oxidize to a lesser extent than copper. In the selection of oxidizable metals, a typical thickness for a diffusion layer would be on the order of ten to 20 angstroms.

FIG. 2 shows a number of vias extending through functional core 120 between surface 280 and surface 290. Representatively, via 250 and via 260 are lined with electrically conductive materials 255 and 265 (e.g., a copper material), respectively, of suitable polarity to be connected to power or ground contact points of die 110 (e.g., through conductive bump layer 125 to contact pads on die 110 of FIG. 1). In one embodiment, vias 250 and vias 260 extend through capacitor structure 140, core substrate 160, and capacitor structure 150. In addition to the conductive material lining, each via may include a plug resin that fills the vias. Electrically conductive portions of vias 250 and vias 260 may be insulated, where desired, from portions of capacitor structure 140 or capacitor structure 150 by sleeves 270 of a dielectric material.

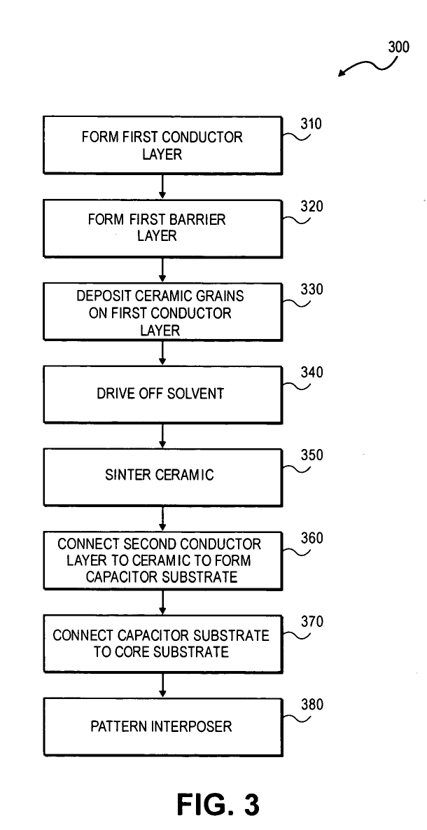

FIG. 3 shows one technique for forming capacitor layer 140. Referring to FIG. 3, method or technique 300 includes initially forming a first conductive layer at block 310. Representatively, a first conductive layer, such as first conductive layer 210 of FIG. 2 is a nickel or copper material that is formed as a sheet (e.g., foil) having a desired thickness. Representative thicknesses are on the order of several microns to tens of microns depending on the particular design parameters. One way a conductive layer of sheet or foil may be formed is by electroplating a material foil or layer on a removable base substrate (e.g., a polymer carrier sheet) having, for example, a conductive seed layer on a surface thereof. Alternatively, a conductive material paste (e.g., copper or nickel paste) may be deposited on the removable base substrate.

Following the formation of a barrier layer, technique or method 300 provides forming a barrier layer. A barrier layer of an oxidation-resistant metal, conductive ceramic, or partially oxidizable metal may be formed by sputtering or other techniques.

Following the formation of a barrier layer, technique or method 300 provides depositing ceramic grains on a surface, including the entire surface, of the first conductive layer, block 330. To form a ceramic material of a thickness on the order of 0.1 to 0.2 micron, ceramic powder particles having a thickness on the order of five to 30 nanometers are deposited on the first conductive layer. One way to deposit ceramic material is through a chemical solution deposition (e.g., sol-gel) process where the metal cations are embedded in polymer chains which are dissolved in a solvent, and the solvent spun or sprayed on to the first conductive layer. Other techniques for depositing ceramic material is by chemical vapor deposition (CVD), physical vapor deposition (PVD), or laser ablation.

Referring to technique or method 300 of FIG. 3, in the embodiment where ceramic material is deposited through a solvent, such as in a sol gel process, once deposited, the deposits are dried to burn-off organic contents, block 340. Representatively, the first conductive layer having deposited ceramic grains thereon is exposed to an inert atmosphere (e.g., nitrogen) and an elevated temperature (e.g., 100 to 200° C.) to drive off the solvent and remove organic contents.

The ceramic particles are exposed to a sintering process to densify or reduce the surface energy of the ceramic particles, block 350. Representative sintering conditions for sintering a high k ceramic, such as BaTiO₃ is a temperature on the order of 700° C. to 900° C. The sintering may be done in an oxidizing atmosphere since the barrier layer on a first conductive layer of, for example, copper, will inhibit the diffusion and/or oxidation of the copper material. The oxidative atmosphere tends to improve the capacitance value of the structure and minimize leakage relative to reducing atmospheres, although reducing atmospheres may still be employed.

Referring to FIG. 3, following the sintering of the ceramic material, a second conductive layer may be connected (e.g., printed, electroplated) to the ceramic material to form a capacitor substrate, block 360. In the embodiment where the ceramic overlies a sheet or foil of the first conductive layer, the second conductive layer may be disposed on an opposite surface of the ceramic material. In one embodiment, the second conductive layer is a metal such as nickel or copper. In an alternate process, the second conductive layer is formed on the ceramic material prior to sintering the ceramic material. In such case, a barrier layer such as described above may be formed between the ceramic material and the second conductive layer.

The capacitor substrate may then be connected (e.g., laminated) to a core substrate such as core substrate 160 in FIG. 3, block 370. In one embodiment, a second capacitor substrate may be formed in a similar manner as provided above and connected to an opposite side of a core substrate to yield the structure shown in FIG. 3.

Following the connection of the capacitor substrate(s) to the core substrate layer, to form an integrated capacitor structure, the integrated capacitor structure is patterned, block 380. Conventional patterning operations, such as mechanical drilling, drilling via holes in epoxy with laser, lithography and copper plating operations used in via formation may be employed. The capacitor structure may also be patterned to form individual capacitors. A complete organic substrate may be formed by adding build-up layers of an organic material onto the structure.

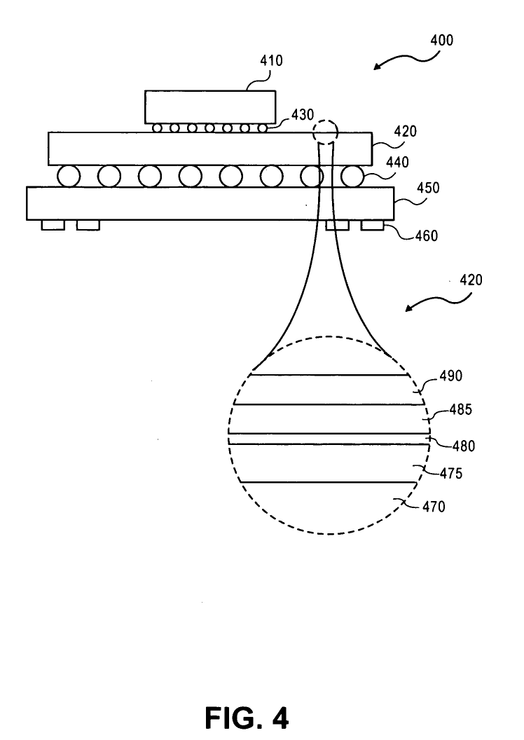

FIG. 4 shows another embodiment of a die or chip assembly. Assembly 400 includes die or chip 410. Electrical contact points (e.g., contact pads) on a surface of die 410 are connected to interposer 420 through conductive bump layer 430. Base substrate 450 is, for example, a package substrate, that may be used to connect assembly 400 to a printed circuit board, such as a motherboard or other circuit board. Interposer 420 is electrically connected to base substrate 450 through conductive bump layer 440 that aligns, for example, contact pads on a surface of interposer 420 with contact pads on the surface of base substrate 450. FIG. 4 also shows surface mount capacitors 460 that may optionally be connected to base substrate 450.

FIG. 4 shows a magnified view of a portion of interposer 420. Interposer 420 includes interposer substrate 470, first conductive layer 475 (electrically conductive) disposed on interposer substrate 470, barrier layer 480 disposed on first conductive layer 475, dielectric layer 485 disposed on barrier layer 480, and second conductive layer 490 (electrically conductive) disposed on dielectric layer 485. In one embodiment, interposer substrate 470 is a ceramic interposer. Interposer substrate 470 is, for example, a ceramic material having a relatively low dielectric constant. Representatively, a low dielectric constant (low-k) material is a ceramic material having a dielectric constant on the order of 10. Suitable materials include, but are not limited to, a glass ceramic or aluminum oxide (e.g., Al₂O₃).

In one embodiment, first conductive layer 475 and second conductive layer 490 are selected from a material that may be deposited to a thickness on the order of a few microns or more. Suitable materials for first conductive layer 475 and second conductive layer 490 include, but are not limited to, copper and nickel material. In one embodiment, dielectric layer 485 is a ceramic material having a relatively high dielectric constant (high-k). Representatively, a high-k material is a ceramic material having a dielectric constant on the order of 1000. Suitable materials for dielectric layer 485 include, but are not limited to, barium titanate (BaTiO₃), barium strontium titanate (Ba, Sr)TiO₃, and strontium titanate (SrTiO₃). In one embodiment, dielectric layer 485 of a high-k ceramic material is formed to a thickness of one micron or less.

In one embodiment, barrier layer 480 is a material that will inhibit the diffusion of atoms of a material for first conductive layer 475. In another embodiment, barrier layer 480 is a material that will inhibit the oxidation of a material of first conductive layer 475. In another embodiment, barrier layer 480 is a material that will inhibit both diffusion of atoms from a material from a material for first conductive layer 475 and inhibit the oxidation of a material of first conductive layer 475. Suitable materials for barrier layer 480 include oxidation resistant metals, conductive ceramics, and metal materials that form stable oxides such as described above with reference to FIG. 2 and barrier layer 225.

An interposer structure such as described above may be formed in a manner similar to the method described above with respect to FIG. 3 and the accompanying text. A capacitor could be formed then laminated to a surface of an interposer substrate. The interposer containing the capacitor could then be patterned as desired.

In the above description, at least a portion of a capacitor structure was exposed to annealing (sintering) conditions to reduce the surface energy of the dielectric material (e.g., a dielectric high k ceramic material). As noted, such annealing conditions are typically on the order of 700° C.-900° C. for several hours. In another embodiment, an alternative annealing process may be employed using, for example, rapid thermal processing or rapid thermal annealing. In this process, a capacitor structure is exposed to a desired temperature range for a duration of a few seconds to a few minutes. Representatively, the capacitor structure is subjected to a desired process temperature to reduce the surface energy of the dielectric material only long enough to achieve the reduced surface energy effect. Thus, to reduce the surface energy of a one micron thick or less high k ceramic material requires only a few minutes at a processing temperature.

In one embodiment, the rapid thermal annealing process may be employed as an alternative to densify or reduce the surface energy of a dielectric material of a capacitor described above with respect to FIG. 3 (e.g., block 350 and the accompanying text). In another embodiment, a capacitor structure may be formed without a barrier layer between a dielectric material at one or more conductive layers. In such case, a high k dielectric material may be formed directly, for example, on a copper electrode and sintered under rapid thermal annealing conditions to reduce the surface energy of the high k dielectric material.

In one embodiment, a rapid thermal anneal may take place in conventional rapid thermal processing (RTP) chamber. Representatively, such chambers utilize radiant heating and also precise controlled time and temperature.

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

1. A method comprising:
forming a barrier material on a surface of an electrode of a capacitor structure;
forming a ceramic material on the electrode material; and
annealing the ceramic material,
wherein the barrier material comprises a material having a property that inhibits the oxidation of a material for the electrode during annealing of the ceramic material.

2. The method of claim 1, wherein the electrode material comprises a copper material.

3. The method of claim 2, wherein the barrier material comprises a conductive material.

4. The method of claim 3, wherein the conductive material comprises an oxidative-resistive metal.

5. The method of claim 3, wherein the conductive material comprises a conductive ceramic.

6. The method of claim 1, wherein the ceramic material has a thickness on the order of one micron or less.

7. The method of claim 1, wherein the electrode material is a first electrode material and after annealing the ceramic material, the method further comprises:
coupling a second electrode material to the ceramic material.

8. An apparatus comprising:
a first electrode;
a second electrode;
a ceramic material disposed between the first electrode and the second electrode; and
a barrier material between the ceramic material and at least one of the first electrode and the second electrode,
wherein the barrier material comprises a material having a property that inhibits the oxidation of a material for the at least one of the first electrode and the second electrode.

9. The apparatus of claim 8, wherein at least one of the first electrode and the second electrode comprises a copper material.

10. The apparatus of claim 8, wherein the barrier material comprises a conductive material.

11. The apparatus of claim 10, wherein the conductive material comprises an oxidative-resistive metal.

12. The apparatus of claim 10, wherein the conductive material comprises a conductive ceramic.

13. The apparatus of claim 8, wherein the ceramic material has a thickness on the order of one micron or less.

14. A method comprising:
forming a ceramic material on a surface of an electrode of a capacitor structure; and
annealing the ceramic material through a rapid thermal anneal process.

15. The method of claim 14, wherein the ceramic material has a thickness on the order of one micron or less.

16. The method of claim 15, wherein the electrode comprises a copper material.
